(19) United States
(12) Patent Application Publication
(10) Pub. No.: US 2021/0173566 A1
(43) Pub. Date: Jun. 10, 2021

(54) CONTROL METHOD OF MEMORY SYSTEM USED FOR REDUCING DELAY TIME

(71) Applicant: Realtek Semiconductor Corp., HsinChu (TW)

(72) Inventors: Ching-Sheng Cheng, HsinChu (TW); Wen-Wei Lin, HsinChu (TW); Kuan-Chia Huang, HsinChu (TW)

(21) Appl. No.: 16/876,097

(22) Filed: May 17, 2020

(30) Foreign Application Priority Data
Dec. 4, 2019 (TW) 108144290

(51) Int. Cl. G06F 3/06; G06F 1/08

(52) U.S. Cl. CPC G06F 3/0611; G06F 1/08; G06F 3/0673; G06F 3/0659

(57) ABSTRACT

A control method of a memory system is disclosed. The memory system includes a controller, an interface and a memory. The interface is coupled to the controller, and the memory is coupled to the controller through the interface. The control method includes the controller sending a clock signal to the memory through the interface, and the controller sending an access command to the memory through the interface to access data at an access address of the memory. The clock signal has a clock period. A time span for the controller to send the access command to the memory is substantially 1.5 clock periods.

### BACKGROUND OF THE INVENTION

### 1. Field of the Invention

The disclosure is related to a control method of a memory system, and more particularly, a control method of memory system where a time span for sending an access command is substantially 1.5 clock periods.

### 2. Description of the Prior Art

As demand for electronic products and communications-related applications continues to grow, memory has played a key role. In order to access more data in the same time duration, the bandwidth requirements of a system for data access continue to increase.

However, for the interface of accessing the memory, the issue of time margin at the memory device side has become a design challenge for integrated circuits (ICs) and printed circuit boards (PCBs). In addition to improving the speed of memory access, the correctness of memory access must also be considered to avoid wrong accesses. Therefore, there is still a lack of suitable solutions in the field to balance the speed and accuracy of memory access.

### SUMMARY OF THE INVENTION

An embodiment discloses a control method of a memory system. The memory system includes a controller, an interface coupled to the controller, and a memory coupled to the controller through the interface. The control method includes the controller sending a clock signal to the memory through the interface wherein the clock signal has a clock period, and the controller sending a first access command to the memory through the interface to access data at a first access address of the memory. A time span for the controller to send the first access command to the memory is substantially 1.5 clock periods.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a memory system according to an embodiment.

FIG. 2 is a flowchart of a control method of the memory system in FIG. 1.

FIG. 3 shows signals and commands transmitted in the memory system in FIG. 1.

FIG. 4 illustrates the memory system of FIG. 1 according to another embodiment.

FIG. 5 to FIG. 7 show signals and commands transmitted in the memory system in FIG. 4.

### DETAILED DESCRIPTION

A time span for sending a command used to control a memory may be an importance parameter in the field of memory control. For example, if a time span for sending a command used to control a memory is set to be one clock period, the time margin may be insufficient and the signal distortion may be increased. Under this condition, the openness of an eye diagram may be insufficient. However, if a time span for sending a command is set longer, for example, to be two clock periods, although the time margin may be effectively increased, and the openness of the eye diagram may be larger, the number of commands sent during a time interval may be reduced so that the operation speed may be lowered. In addition, there may be two sorts of commands: access command and active command. Regarding an active command to be sent between access commands, access commands may be further delayed.

According to embodiments, commands used for reading and programming may be access commands, and commands for other purposes may be active commands. Each command may be corresponding to a combination of logic states of a plurality of signals, and the combination can be planned in a truth table. In the text, for example, an access command may be a column address strobe (CAS) command. The column address strobe command may be used to access data of a memory bank address, that is, data of a row and a column. An active command may be a command other than an access command. The active command may include a precharge (PRE) command, a mode register set (MRS) command, a row address strobe (RAS) command and/or a refresh (REF) command. The RAS command can be used to activate a bank row such as a page.

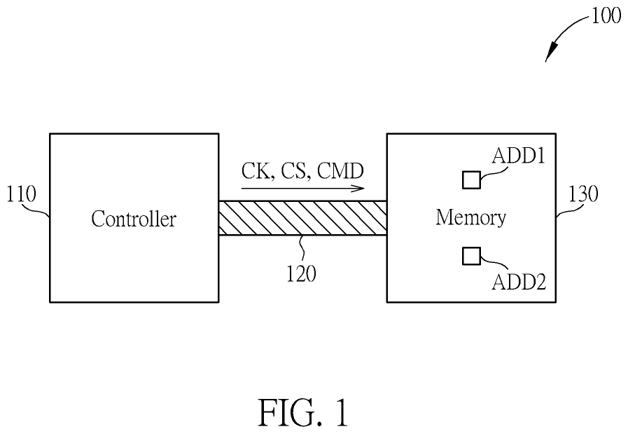

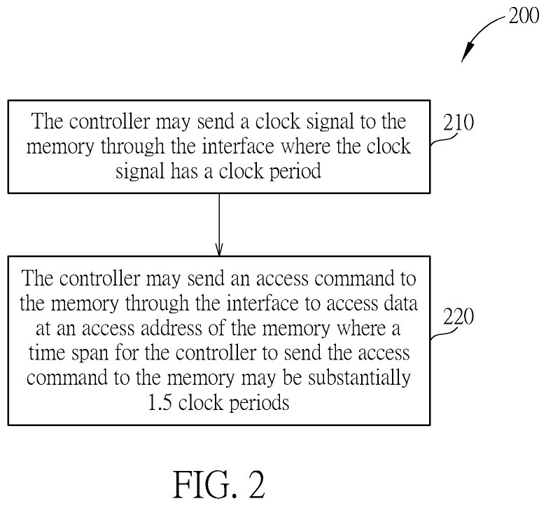

FIG. 1 illustrates a memory system 100 according to an embodiment. FIG. 2 is a flowchart of a control method 200 of the memory system 100 in FIG. 1.

The memory system 100 may include a controller 110, an interface 120 and a memory 130. The interface 120 may be coupled between the controller 110 and the memory 130.

The controller 110 may include a memory controller (MC). The memory 130 may be a double data rate (DDR) memory. The interface 120 may be a double data rate physical interface (DFI).

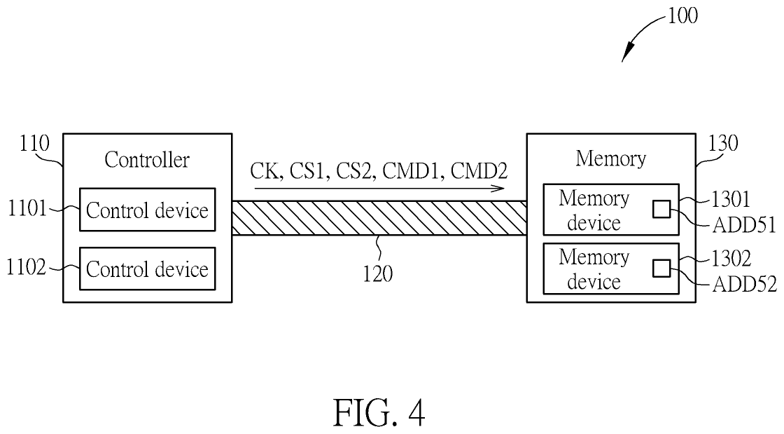

According to an embodiment, the memory system 100 may include a single control device, a single interface and a single memory device. According to another embodiment, the memory system 100 may include a plurality of control devices, a single interface and a plurality of memory devices. Hence, as described below, the controller 110 may include a plurality of control devices, and the memory 130 may include a plurality of memory devices as shown in FIG. 4.

As shown in FIG. 1 and FIG. 2, the control method 200 may include the following steps.

Step 210: the controller 110 may send a clock signal CK to the memory 130 through the interface 120 where the clock signal CK has a clock period Tck; and

Step 220: the controller 110 may send an access command to the memory 130 through the interface 120 to access data at an access address ADD1 of the memory 130 where a time span Tcmd for the controller 110 to send the access command to the memory 130 may be substantially 1.5 clock periods Tck.

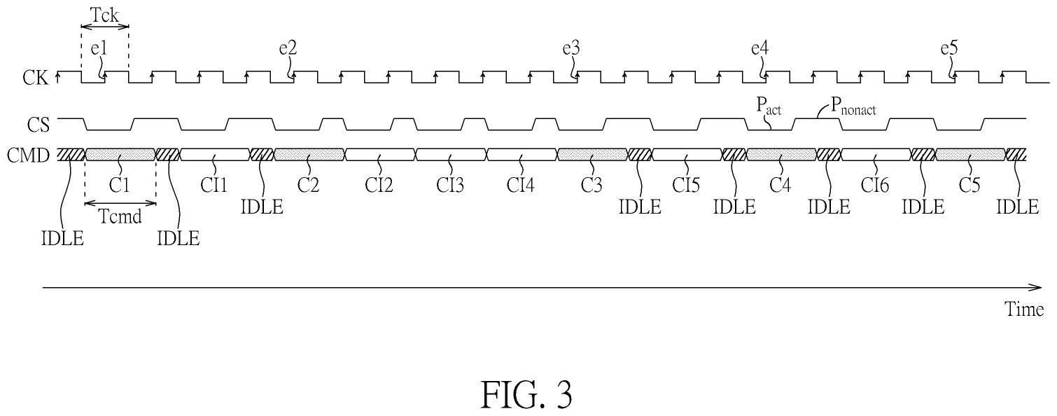

FIG. 3 shows signals and commands transmitted in the memory system 100 in FIG. 1. In FIG. 3, a horizontal arrow from left to right is a time line. FIG. 3 may show signals and commands sent in a case where a single controller controls a single memory device through a single interface. In FIG. 3, a column to column delay (often referred to as tCCD) may be substantially six clock periods. In FIG. 3, a command signal CMD is corresponding to commands sent by the controller 110. The command signal CMD may be corresponding to a plurality of commands, and the commands may be planned in a truth table. Likewise, in the following, each of the command signals CMD1 and CMD2 in FIG. 4 may be substantially corresponding to a plurality of commands.

As shown in FIG. 3, a time span for sending an access command C1 may be substantially 1.5 clock periods Tck. The controller 110 may send an access command C2 to the memory 130 through the interface 120 to access data at an access address ADD2 of the memory 130. A time span for the controller 110 to send the access command C2 to the memory 130 may be substantially 1.5 clock periods Tck. In FIG. 3, the access command C1 may be sent before sending the access command C2. Likewise, after sending the access command C2, the controller 110 may send access commands C3, C4 and C5 to the memory 130 through the interface 120.

As shown in FIG. 2 and FIG. 3, the controller 110 may send an active command CI1 to the memory 130 through the interface 120. The active command CI1 may be sent between the access command C1 and the access command C2 along the time line. Likewise, between a time of sending the access command C2 and a time of sending the access command C3, the controller 110 may send active commands CI2, CI3 and CI4 to the memory 130. In addition, the controller 110 may further send active commands CI5 and CI6. Between times of sending two commands, if it is unable to send another command, there may be an idle status. According to an embodiment, a time span for sending an active command may be substantially 1.5 clock periods Tck.

As shown in FIG. 3, the controller 110 may send a chip selection signal CS to the memory 130 through the interface 120. The chip selection signal CS may have an active pulse P_{act} and a non-active pulse P_{nonact}. For example, the active pulse P_{act} may be at a low state, and the non-active pulse P_{nonact} may be at a high state. According to an embodiment, a time length of the active pulse P_{act} of the chip selection signal CS may be substantially equal to the clock period Tck, and a time length of the non-active pulse P_{nonact} may be adjusted according to requirements.

The chip selection signal CS may be used to select a chip corresponding to the memory 130 and select a command being sent. When the clock signal CK is at a specific signal edge (e.g., a rising edge or a falling edge), and the chip selection signal CS is at the active pulse P_{act}, a command being sent may be selected accordingly.

For example, when the clock signal CK is at a rising edge e1, because the chip selection signal CS is at the active pulse P_{act} (e.g., a low state), a command being set at the time (i.e. the access command C1) may be selected. Likewise, as shown in FIG. 3, at rising edges e2 to e5, the access commands C2 to C5 may be respectively selected since the chip selection signal CS is at the active pulses P_{act}.

As shown in FIG. 3, by setting the time span for sending an access command to be 1.5 clock periods Tck, between times of sending the access commands C2 and C3, three active commands (e.g., CI2, CI3 and CI4) may be sent along the time line due to the time spans for sending the commands. In this condition, the openness of an eye diagram may be better than that where the time span for sending an access command is merely one time clock period Tck. In another condition, when the time span for sending an access command is two clock periods Tck, between times of sending two access commands, at most two active commands may be sent. Hence, by setting the time span for sending an access command to be 1.5 clock periods Tck, the operation speed and the correctness of accessing data can be both taken into account and balanced, and the openness of an eye diagram can be sufficient.

FIG. 4 illustrates the memory system 100 of FIG. 1 according to another embodiment. As in FIG. 1, the memory system 100 may include the controller 110, the interface 120 and the memory 130. However, in FIG. 4, the controller 110 may include control devices 1101 and 1102, and the memory 130 may include memory devices 1301 and 1302. In other words, FIG. 4 shows that a plurality of control devices may control a plurality of memory devices through a single interface. For example, in FIG. 4, the memory devices 1301 and 1302 may be double data rate memory devices of different chips, and the control devices 1101 and 1102 may be used to respectively control the memory devices 1301 and 1302.

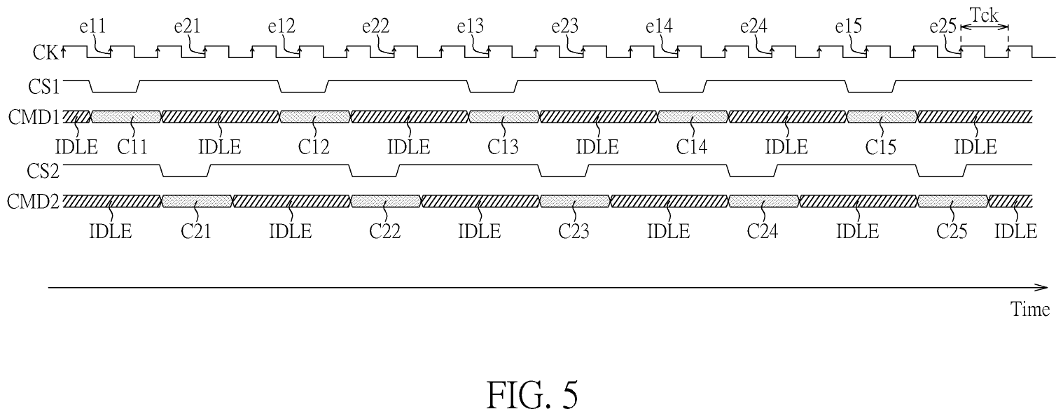

FIG. 5 to FIG. 7 illustrate signals and commands transmitted in the memory system 100 in FIG. 4. The clock signal CK of FIG. 5 may have a clock period Tck as shown in FIG. 3. The command signal CMD1 of FIG. 5 may be corresponding to commands sent by the control device 1101 to the memory device 1301, and the command signal CMD2 may be corresponding to commands sent by the control device 1102 to the memory device 1302.

When the chip selection signal CS1 is at the active pulse P_{act} (e.g., a low state), the memory device 1301 may be selected. When the chip selection signal CS2 is at the active pulse P_{act} (e.g., a low state), the memory device 1302 may be selected. Because the interface 120 of FIG. 5 is a single interface, the chip selection signals CS1 and CS2 may not be at the active pulse P_{act} at the same time.

As shown in FIG. 5, when the clock signal CK is at rising edges e11, e12, e13, e14 and e15, because the chip selection signal CS1 is at the active pulses P_{act}, access commands C11, C12, C13, C14 and C15 may be respectively selected. Likewise, when the clock signal CK is at rising edges e21, e22, e23, e24 and e25, because the chip selection signal CS2 is at the active pulses P_{act}, access commands C21, C22, C23, C24 and C25 may be respectively selected. The control device 1101 may send the access commands C11 to C15 to access the memory device 1301, and the control device 1102 may send the access commands C21 to C25 to access the memory device 1302.

As shown in FIG. 4 and FIG. 5, if regarding the access commands C11 and C12 as a first access command and a second access command, an access address ADD51 described in the first access command may be in the memory device 1301, and an access address ADD52 described in the second access command may be in the memory device 1302. The first access command may be sent by the control device 1101 to the memory 130, and the second access command may be sent by the control device 1102 to the memory 130.

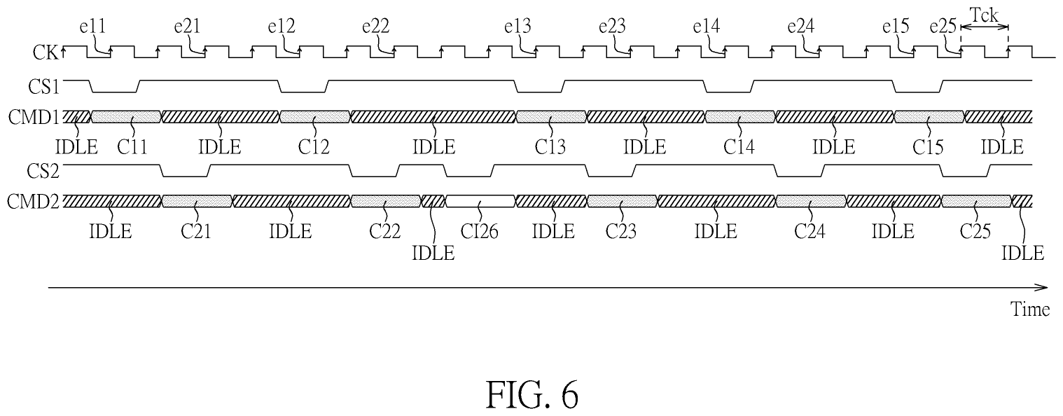

FIG. 5 merely illustrates a scenario of sending access commands. Comparing with FIG. 5, FIG. 6 further illustrates another condition where the command signal CMD2 is also corresponding to active commands. In other words, FIG. 5 illustrates a scenario without considering active command, and FIG. 6 further illustrates the control device 1102 may send active commands. Comparing with FIG. 5, as shown in FIG. 6, an active command CI26 may be sent between the access commands C22 and C23. Hence, from FIG. 5 to FIG. 6, the rising edge e13 corresponding to selecting the access command C13 is substantially delayed by one clock period Tck.

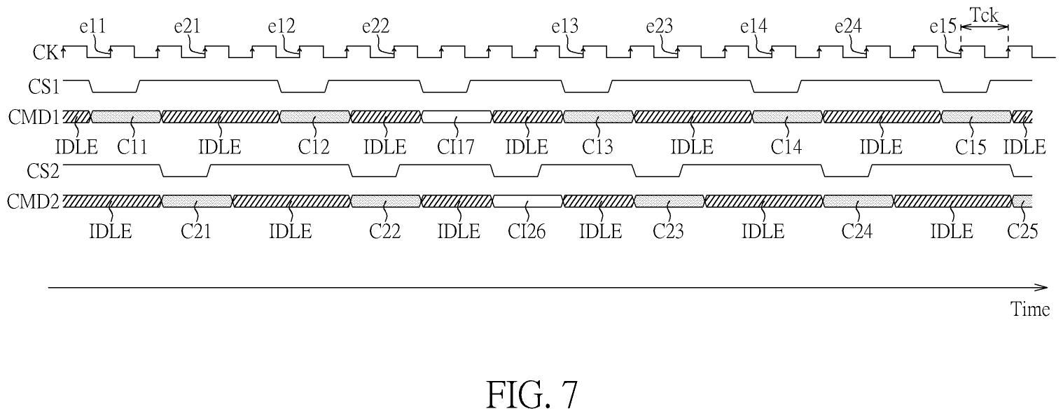

Comparing with FIG. 5, FIG. 7 illustrates another scenario where the command signals CMD1 and CMD2 are also corresponding to active commands. In other words, FIG. 7 further illustrates a scenario where the control devices 1101 and 1102 may send active commands. Comparing with FIG. 6, as shown in FIG. 7, an active command CI17 may be sent between the access commands C12 and C13. Hence, from FIG. 5 to FIG. 7, the rising edge e13 corresponding to selecting the access command C13 is substantially delayed by two clock periods Tck.

In a scenario where the time span for sending each command is two clock periods Tck, when the command signals CMD1 and CMD2 include active commands, a rising edge of a clock signal corresponding to a same access command will be delayed by four clock periods Tck. Hence, as the example of FIG. 7, by adjusting the time span for sending a command from two clock periods Tck to 1.5 clock periods Tck, the delayed time of accessing a command will be reduced from four clock periods Tck to two clock periods Tck. The delayed time of accessing a command may be reduced by 50%, and the eye diagram will be better than the eye diagram where the time span for sending the command is merely one clock period Tck.

According to another embodiment, the memory system 100 of FIG. 1 may include another memory in addition to the memory 130. The control method 200 of FIG. 2 may further include the controller 110 sending another clock signal to the another memory through the interface 120. The clock signal CK (described in FIG. 1) and the abovementioned another clock signal may have the same frequency and be of different phases. For example, the memory system 100 may include N memories, and the controller 110 may send N clock signals to the N memories respectively through the interface 120, where the N clock signals may have the same frequency and be of different phases, and N is a positive integer larger than one.

In summary, by setting the time span for sending a command to be 1.5 clock periods, the operation speed and correctness of accessing data can be both taken into account and balanced, and sufficient openness can be measured in the eye diagram. Hence, the problems in the field can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A control method of a memory system, the memory system comprising a controller, an interface coupled to the controller, and a memory coupled to the controller through the interface, the control method comprising:
the controller sending a clock signal to the memory through the interface wherein the clock signal has a clock period; and
the controller sending a first access command to the memory through the interface to access data at a first access address of the memory wherein a time span for the controller to send the first access command to the memory is substantially 1.5 clock periods.

2. The control method of claim 1, further comprising:
the controller sending a second access command to the memory through the interface to access data at a second access address of the memory wherein a time span for the controller to send the second access command to the memory is substantially 1.5 clock periods.

3. The control method of claim 2, wherein sending the first access command is before sending the second command.

4. The control method of claim 2, wherein the first access address is in a first memory device of the memory, and the second access address is in a second memory device of the memory.

5. The control method of claim 2, wherein the first access command is sent to the memory by a first control device of the controller, and the second access command is sent to the memory by a second control device of the controller.

6. The control method of claim 2, further comprising:
the controller sending an active command to the memory through the interface.

7. The control method of claim 6, wherein the active command comprises a precharge command, a mode register set command, a row address strobe command and/or a refresh command.

8. The control method of claim 7, wherein the row address strobe command is used to activate a bank row.

9. The control method of claim 6, wherein the active command is sent between the first access command and the second access command.

10. The control method of claim 1, further comprising:
the controller sending a chip selection signal to the memory through the interface;
wherein the chip selection signal has an active pulse and a non-active pulse.

11. The control method of claim 10, wherein the chip selection signal is used to select a chip corresponding to the memory and select a command being sent.

12. The control method of claim 10, wherein the chip selection signal is used to select a chip corresponding to the memory and select a command being sent at a specific edge of the clock signal.

13. The control method of claim 12, wherein the specific edge of the clock signal is a rising edge or a falling edge.

14. The control method of claim 10, wherein a time length of the active pulse of the chip selection signal is substantially equal to the clock period.

15. The control method of claim 1, wherein the memory is a double data rate memory.

16. The control method of claim 1, wherein the interface is a double data rate physical interface.

17. The control method of claim 1, wherein the controller comprises a memory controller.

18. The control method of claim 1, wherein the memory system further comprises another memory, and the control method further comprises:
the controller sending another clock signal to the another memory through the interface;
wherein the clock signal and the another clock signal have a same frequency and are of different phases.
